(19) United States
(12) Patent Application Publication
(10) Pub. No.: US 2010/0144160 A1
(43) Pub. Date: Jun. 10, 2010

(54) PLASMA REACTOR SUBSTRATE MOUNTING SURFACE TEXTURING

(75) Inventors: JOHN M. WHITE, Hayward, CA (US); Zhifei Ye, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/628,016

(22) Filed: Nov. 30, 2009

Related U.S. Application Data
(63) Continuation of application No. 11/566,113, filed on Dec. 1, 2006, now abandoned.

(51) Int. Cl. H01L 21/302; B05C 13/00

(52) U.S. Cl. 438/758; 118/500; 118/58; 257/E21.214

(57) ABSTRACT

The present invention generally provides apparatus and methods for providing necessary capacitive decoupling to a large area substrate in a plasma reactor. One embodiment of the invention provides a substrate support for using in a plasma reactor comprising an electrically conductive body has a top surface with a plurality of raised areas configured for contacting a back surface of a large area substrate, and the plurality of raised areas occupy less than about 50% of the surface area of the top surface.

### CROSS REFERENCE TO RELATED APPLICATIONS

This patent application is a continuation of a co-pending U.S. patent application Ser. No. 11/566,113 (Attorney Docket No. 11494), filed Dec. 1, 2006, which is incorporated herein by reference.

### BACKGROUND OF THE INVENTION

1. Field of the Invention

Embodiments of the present invention generally relate to an apparatus and method for processing large area substrates. More particularly, embodiments of the present invention relate to a substrate support for supporting large area substrates in semiconductor processing and a method of fabricating the same.

2. Description of the Related Art

Equipment for processing large area substrates has become a substantial investment in manufacturing of flat panel displays including liquid crystal displays (LCDs) and plasma display panels (PDPs), organic light emitting diodes (OLEDs), and solar panels. A large area substrate for manufacturing LCD, PDP, OLED or solar panels may be a glass or a polymer workpiece.

The large area substrate is typically subjected to a plurality of sequential processes to created devices, conductors, and insulators thereon. Each of these processes is generally performed in a process chamber configured to perform a single step of the production process. In order to efficiently complete the entire sequential processes, a number of process chambers are typically used. One fabrication process frequently used to process a large area substrate is plasma enhanced chemical vapor deposition (PECVD).

PECVD is generally employed to deposit thin films on a substrate such as a flat panel substrate or a semiconductor substrate. PECVD is typically performed in a vacuum chamber between parallel electrodes positioned several inches apart, typically with a variable gap for process optimization. A substrate being processed may be disposed on a temperature controlled substrate support disposed in the vacuum chamber. In some cases, the substrate support may be one of the electrodes. A precursor gas is introduced into the vacuum chamber and is typically directed through a distribution plate situated near the top of the vacuum chamber. The precursor gas in the vacuum chamber is then energized or excited into a plasma by applying a RF power coupled to the electrodes. The excited gas reacts to form a layer of material on a surface of the substrate positioned on the substrate support. Typically, a substrate support or a substrate support assembly in a PECVD chamber is configured to support and heat the substrate as well as serve as an electrode to excite the precursor gas.

Generally, large area substrates, for example those utilized for flat panel fabrication, are often exceeding 550 mm×650 mm, and are envisioned up to and beyond 4 square meters in surface area. Correspondingly, the substrate supports utilized to process large area substrates are proportionately large to accommodate the large surface area of the substrate. The substrate supports for high temperature use typically are casted, encapsulating one or more heating elements and thermocouples in an aluminum body. Due to the size of the substrate support, one or more reinforcing members are generally disposed within the substrate support to improve the substrate support's stiffness and performance at elevated operating temperatures (i.e., in excess of 350 degrees Celsius and approaching 500 degrees Celsius to minimize hydrogen content in some films). The aluminum substrate support is then anodized to provide a protective coating.

Although substrate supports configured in this manner have demonstrated good processing performance, two problems have been observed. The first problem is non-uniform deposition. Small local variations in film thickness, often manifesting as spots of thinner film thickness, have been observed which may be detrimental to the next generation of devices formed on large area substrates. It is believed that variation in substrate thickness and flatness, along with a smooth substrate support surface, typically about 50 micro-inches, creates a local capacitance variation in certain locations across the glass substrate, thereby creating local plasma non-uniformities that results on deposition variation, e.g., spots of thin deposited film thickness.

The second problem is caused by the static charge generated by the triboelectric process, or the process of bringing two materials into contact with each other and then separating them from each other. As a result, electrostatics may build up between the substrate and the substrate support making it difficult to separate the substrate from the substrate support once the process is completed.

An additional problem is known in the industry as the electro-static discharge (ESD) metal lines arcing problem. As the substrate size increased, the ESD metal lines become longer and larger. It is believed that the inductive current in the ESD metal lines becomes large enough during plasma deposition to damage the substrate. This ESD metal lines arcing problem has become a major recurring problem.

Therefore, there is a need for a substrate support that provides necessary capacitive decoupling of a substrate being processed from the substrate support and sufficient coupling to provide good film deposition performance.

### SUMMARY OF THE INVENTION

The present invention generally provides apparatus and methods for providing necessary capacitive decoupling to a large area substrate in a plasma reactor.

One embodiment of the invention provides a substrate support for using in a plasma reactor comprising an electrically conductive body configured to be an electrode of the plasma reactor, wherein the electrically conductive body has a top surface configured for supporting a large area substrate and providing heat energy to the large area substrate, the top surface has a plurality of raised areas configured for contacting a back surface of the large area substrate, and the plurality of raised areas occupy less than about 50% of the surface area of the top surface.

Another embodiment of the present invention provides a substrate support for processing a large area substrate comprising an electrically conductive body configured for supporting the large area substrate and providing capacitive decoupling to the large area substrate, wherein the electrically conductive body has a plurality of raised areas evenly distributed on a top surface and continuously connected to a plurality of lowered areas on the top surface, the plurality of raised areas are configured to substantially contact a back surface of the large area substrate, and the plurality of raised areas occupy less than about 50% of the total surface area of the top surface, and a heating element encapsulated in the electrically conductive body.

Yet another embodiment of the present invention provides a method for processing a large area substrate in a plasma chamber comprising providing a substrate support having an electrically conductive body, wherein the electrically conductive body has a top surface configured for supporting a large area substrate and providing heat energy to the large area substrate, the top surface has a plurality of raised areas configured for contacting a back surface of the large area substrate, and the plurality of raised areas occupy less than about 50% of the surface area of the top surface, positioning the large area substrate on the top surface of the substrate support, introducing a precursor gas to the plasma chamber, and generating a plasma of the precursor gas by applying an RF power between the electrically conductive body and an electrode parallel to the electrically conductive body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a cross sectional view of a plasma enhanced chemical vapor deposition chamber in accordance with one embodiment of the present invention.

FIG. 2 schematically illustrates a partial perspective view of a substrate support in a plasma enhanced chemical vapor deposition chamber.

FIG. 3 is a schematic enlarged view of an interface between a substrate and a top surface of a substrate support in accordance with one embodiment of the present invention.

FIG. 4 schematically illustrates one embodiment of a top surface of a substrate support in accordance with one embodiment of the present invention.

FIGS. 5A-D schematically illustrate a sequential process for making a top surface of a substrate support of the present invention.

FIGS. 6A-B schematically illustrate another process for making a top surface of a substrate support of the present invention.

To facilitate understanding, identical reference numerals have been used, where possible, to designate identical elements that are common to the figures. It is to be noted, however, that the appended drawings illustrate only typical embodiments of this invention and are therefore not to be considered limiting of its scope, for the invention may admit to other equally effective embodiments.

### DETAILED DESCRIPTION

The present invention relates to a substrate support that provides necessary capacitive decoupling to a substrate being processed and methods of making the substrate support. Particularly, the substrate support of the present invention reduces the electrostatics between the substrate and the substrate support and to minimize plasmoid which usually appears with damaged substrates. Although not wishing to be bound by theory, it is believed that intensive plasma over metal lines on a large area substrate heats the large area substrate unevenly causing thermal stress in the large area substrate. The thermal stress in the large area substrate may build up large enough to fracture the large area substrate. Once the non-conductive large area substrate is broken, the conductive substrate support is exposed to the plasma, arcing, or plasmoid, occurs. The substrate support of the present invention reduces electrostatics, minimizes plasmoid, as well as provides good film deposition performance.

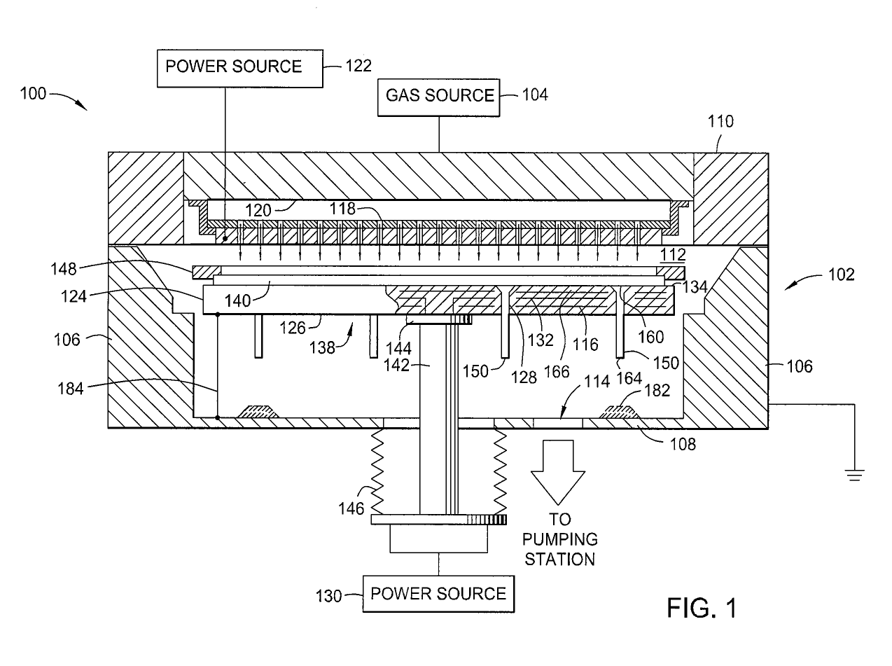

FIG. 1 schematically illustrates a cross sectional view of a plasma enhanced chemical vapor deposition system 100 in accordance with one embodiment of the present invention. The plasma enhanced chemical vapor deposition system 100 is configured to form structures and devices on a large area substrate, for example, a large area substrate for use in the fabrication of liquid crystal displays (LCDs), plasma display panels (PDPs), organic light emitting diodes (OLEDs), and solar panels. The large area substrate being processed may be a glass substrate or a polymer substrate.

The system 100 generally includes a chamber 102 coupled to a gas source 104. The chamber 102 comprises chamber walls 106, a chamber bottom 108 and a lid assembly 110 that define a process volume 112. The process volume 112 is typically accessed through a port (not shown) formed in the chamber walls 106 that facilitates passage of a large area substrate 140 (hereafter substrate 140) into and out of the chamber 102. The substrate 140 may be a glass or polymer workpiece. In one embodiment, the substrate 140 has a plan surface area greater than about 0.25 meters squared. The chamber walls 106 and chamber bottom 108 are typically fabricated from a unitary block of aluminum or other material compatible for plasma processing. The chamber walls 106 and chamber bottom 108 are typically electrically grounded. The chamber bottom 108 has an exhaust port 114 that is coupled to various pumping components (not shown) to facilitate control of pressure within the process volume 112 and exhaust gases and byproducts during processing.

In the embodiment depicted in FIG. 1, the chamber body 102 has a gas source 104, and a power source 122 coupled thereto. The power source 122 is coupled to a gas distribution plate 118 to provide an electrical bias that energizes the process gas and sustains a plasma formed from process gas in the process volume 112 below the gas distribution plate 118 during processing.

The lid assembly 110 is supported by the chamber walls 106 and can be removed to service the chamber 102. The lid assembly 110 is generally comprised of aluminum. The gas distribution plate 118 is coupled to an interior side 120 of the lid assembly 110. The gas distribution plate 118 is typically fabricated from aluminum. The center section of the gas distribution plate 118 includes a perforated area through which process gases and other gases supplied from the gas source 104 are delivered to the process volume 112. The perforated area of the gas distribution plate 118 is configured to provide uniform distribution of gases passing through the gas distribution plate 118 into the chamber 102. Detailed description of the gas distribution plate 118 may be found in U.S. patent application Ser. No. 11/173,210 (Attorney Docket No. 9230 P2), filed Jul. 1, 2005, entitled, “Plasma Uniformity Control by Gas Diffuser Curvature” and U.S. patent application Ser. No. 11/188,922 (Attorney Docket No. 9338), filed Jul. 25, 2005, entitled “Diffuser Gravity Support”, which are hereby incorporated by reference.

A substrate support assembly 138 is centrally disposed within the chamber 102. The substrate support assembly 138 is configured to support the substrate 140 during processing. The substrate support assembly 138 generally comprises an electrically conductive body 124 supported by a shaft 142 that extends through the chamber bottom 108.

The support assembly 138 is generally grounded such that RF power supplied by the power source 122 to the gas distribution plate 118 (or other electrode positioned within or near the lid assembly of the chamber) may excite the gases disposed in the process volume 112 between the support assembly 138 and the gas distribution plate 118. The RF power from the power source 122 is generally selected commensurate with the size of the substrate to drive the chemical vapor deposition process. In one embodiment, the conductive body 124 is grounded through one or more RF ground return path members 184 coupled between a perimeter of the conductive body 124 and the grounded chamber bottom 108. Detailed description of RF ground return path members 184 may be found in U.S. patent application Ser. No. 10/919,457 (Attorney Docket No. 9181), filed Aug. 16, 2004, entitled “Method and Apparatus for Dechucking a Substrate”, which is hereby incorporated by reference.

In one embodiment, at least the portion of the conductive body 124 may be covered with an electrically insulative coating to improve deposition uniformity without expensive aging or plasma treatment of the support assembly 138. The conductive body 124 may be fabricated from metals or other comparably electrically conductive materials. The coating may be a dielectric material such as oxides, silicon nitride, silicon dioxide, aluminum dioxide, tantalum pentoxide, silicon carbide, polyimide, among others, which may be applied by various deposition or coating processes, including but not limited to, flame spraying, plasma spraying, high energy coating, chemical vapor deposition, spraying, adhesive film, sputtering and encapsulating. Detailed description of the coating may be found in U.S. patent application Ser. No. 10/435,182 (Attorney Docket No. 8178), filed May 9, 2003, entitled “Anodized Substrate Support”), and U.S. patent application Ser. No. 11/182,168 (Attorney Docket No. 8178 P1), filed Jul. 15, 2005, entitled “Reduced Electrostatic Charge by Roughening the Susceptor”, which are hereby incorporated by reference.

In one embodiment, the conductive body 124 encapsulates at least one embedded heating element 132. At least a first reinforcing member 116 is generally embedded in the conductive body 124 proximate the heating element 132. A second reinforcing member 166 may be disposed within the conductive body 124 on the side of the heating element 132 opposite the first reinforcing member 116. The reinforcing members 116 and 166 may be comprised of metal, ceramic or other stiffening materials. In one embodiment, the reinforcing members 116 and 166 are comprised of aluminum oxide fibers. Alternatively, the reinforcing members 116 and 166 may be comprised of aluminum oxide fibers combined with aluminum oxide particles, silicon carbide fibers, silicon oxide fibers or similar materials. The reinforcing members 116 and 166 may include loose material or may be a pre-fabricated shape such as a plate. Alternatively, the reinforcing members 116 and 166 may comprise other shapes and geometry. Generally, the reinforcing members 116 and 166 have some porosity that allows aluminum to impregnate the members 116, 166 during a casting process described below.

The heating element 132, such as an electrode disposed in the support assembly 138, is coupled to a power source 130 and controllably heats the support assembly 138 and the substrate 140 positioned thereon to a desired temperature. Typically, the heating element 132 maintains the substrate 140 at a uniform temperature of about 150 to at least about 460 degrees Celsius. The heating element 132 is generally electrically insulated from the conductive body 124.

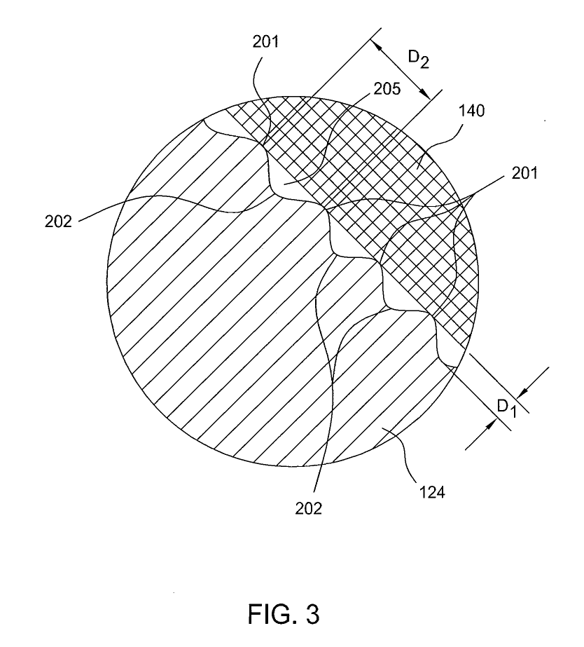

The conductive body 124 has a lower side 126 and a top surface 134 configured to support the substrate 140 and provide heat energy to the substrate 140. The top surface 134 may be roughened so that space pockets 205 (as shown in FIG. 3) may be formed between the top surface 134 and the substrate 140. The space pockets 205 reduce capacitive coupling between the conductive body 124 and the substrate 140. In one embodiment, the top surface 134 may be a non-planar surface configured to be partially in contact with the substrate 140 during process.

The lower side 126 has a stem cover 144 coupled thereto. The stem cover 144 generally is an aluminum ring coupled to the support assembly 138 that provides a mounting surface for the attachment of the shaft 142 thereto.

The shaft 142 extends from the stem cover 144 and couples the support assembly 138 to a lift system (not shown) that moves the support assembly 138 between an elevated position (as shown) and a lowered position. A bellows 146 provides a vacuum seal between the process volume 112 and the atmosphere outside the chamber 102 while facilitating the movement of the support assembly 138.

The support assembly 138 additionally supports a circumscribing shadow frame 148. Generally, the shadow frame 148 prevents deposition at the edge of the substrate 140 and support assembly 138 so that the substrate does not stick to the support assembly 138.

The support assembly 138 has a plurality of holes 128 formed therethrough that accept a plurality of lift pins 150. The lift pins 150 are typically comprised of ceramic or anodized aluminum. Generally, the lift pins 150 have first ends 160 that are substantially flush with or slightly recessed from a top surface 134 of the support assembly 138 when the lift pins 150 are in a normal position (i.e., retracted relative to the support assembly 138). The first ends 160 are generally flared or otherwise enlarged to prevent the lift pins 150 from falling through the holes 128. Additionally, the lift pins 150 have a second end 164 that extends beyond the lower side 126 of the support assembly 138. The lift pins 150 come in contact with the chamber bottom 108 and are displaced from the top surface 134 of the support assembly 138, thereby placing the substrate 140 in a spaced-apart relation to the support assembly 138.

In one embodiment, lift pins 150 of varying lengths are utilized so that they come into contact with the bottom 108 and are actuated at different times. For example, the lift pins 150 that are spaced around the outer edges of the substrate 140, combined with relatively shorter lift pins 150 spaced inwardly from the outer edges toward the center of the substrate 140, allow the substrate 140 to be first lifted from its outer edges relative to its center. In another embodiment, lift pins 150 of a uniform length may be utilized in cooperation with bumps or plateaus 182 positioned beneath the outer lift pins 150, so that the outer lift pins 150 are actuated before and displace the substrate 140 a greater distance from the top surface 134 than the inner lift pins 150. Alternatively, the chamber bottom 108 may comprise grooves or trenches positioned beneath the inner lift pins 150, so that the inner lift pins 150 are actuated after and displaced a shorter distance than the outer lift pins 150. Embodiments of a system having lift pins configured to lift a substrate in an edge to center manner from a substrate support that may be adapted to benefit from the invention are described in U.S. Pat. No. 6,676,761, which is hereby incorporated by reference.

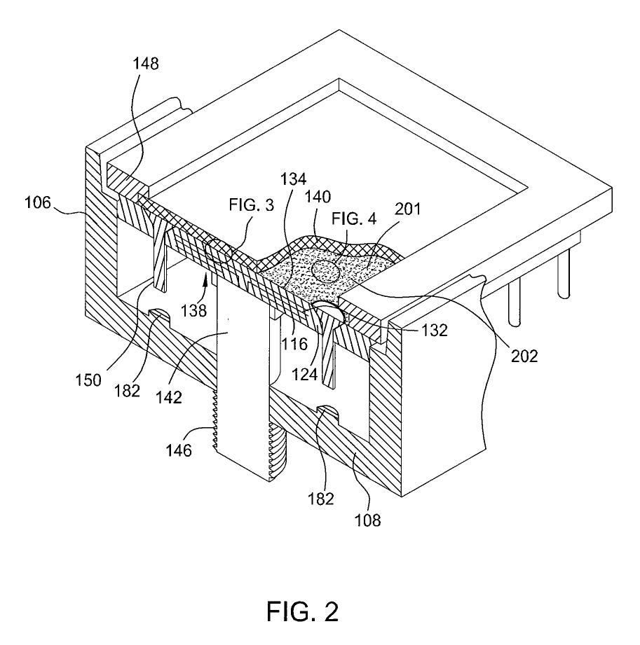

FIG. 2 schematically illustrates a partial perspective view of the substrate support assembly 138 in the plasma enhanced chemical vapor deposition system 100. The conductive body 124 of the substrate support assembly 138 has a textured top surface 134. In one embodiment, the top surface 134 comprises a plurality of raised areas 201 configured to contact the substrate 140 supported thereon and a plurality of lowered areas 202. In one embodiment, the raised areas 201 and neighboring lowered areas 202 are connected in a substantially continuous manner (further described with FIG. 3) to prevent the textured top surface 134 from scratching the substrate 140. The substrate 140 positioned on the conductive body 124 is separated from the lowered areas 202 by the raised areas 201. The raised areas 201 only occupy a limited percentage of the entire top surface 134 to provide the substrate 140 enough capacitive decoupling from the conductive body 124, therefore, avoid metal line arcing and undesired electrostatics. In one embodiment, the raised areas 201 occupy less than about 50% of the entire top surface 134.

FIG. 3 is a schematic enlarged view of an interface between the substrate 140 and the top surface 134 of the conductive body 124. Areas near the raised areas 201 are relatively smooth so that the substrate 140 is not scratched by the top surface 134. In one embodiment, the top surface 134 is a substantially continuous wherein the lowered areas 202 are smoothly connected to neighboring raised areas 201. In one embodiment, the distance D1 between the lowest point of the lowered areas 202 and the highest point of the raised areas 201 is between about 0.001 inch to about 0.002 inch. The distance between neighboring raised areas 201 is between about 0.5 mm to about 3 mm. Preferably, the distance between neighboring raised areas 201 is between about 1 mm to about 2 mm.

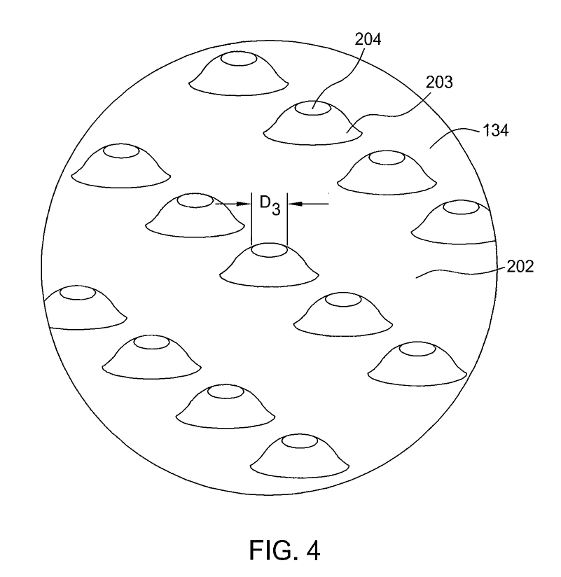

The raised areas 201 may be evenly distributed across the top surface 134. In one embodiment, the raised areas 201 may be an array of islands formed on the top surface 134. In one embodiment, the raised areas 201 may be a plurality of islands in closed packed hexagonal arrangement, as shown in FIG. 4. Referring to FIG. 4, one embodiment of the top surface 134 of the conductive body 124 may have an array of rounded islands 203 formed thereon. Each of the islands 203 may have a flat area 204 configured to be a contact area for a substrate. In one embodiment, the flat area 204 may have a diameter of less than 0.5 mm. Each of the islands 203 may have a smooth surface to avoid scratching of the substrate.

It should be noted that other suitable patterns that provide a smooth contact surface and enough capacitive decoupling may be applied to the top surface 134.

The top surface 134 of the conductive body 124 may be fabricated in various ways, such as for example, chemical etching, electropolishing, texturing, grinding, abrasive blasting, and knurling.

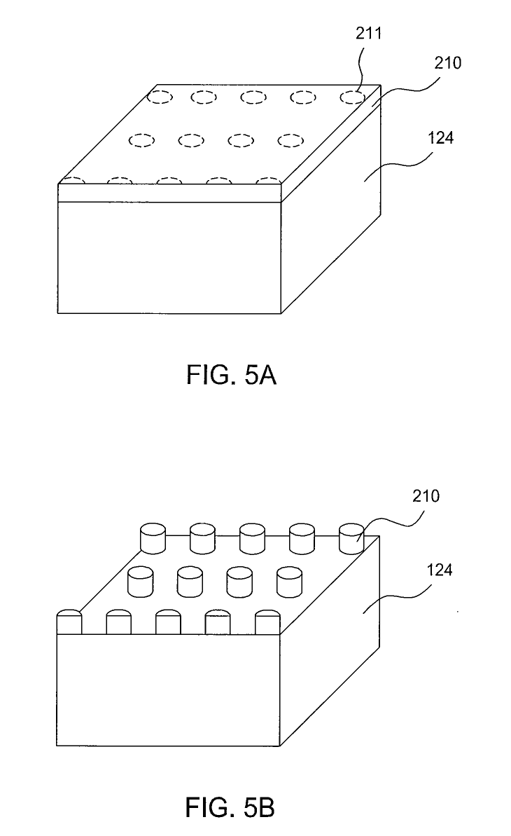

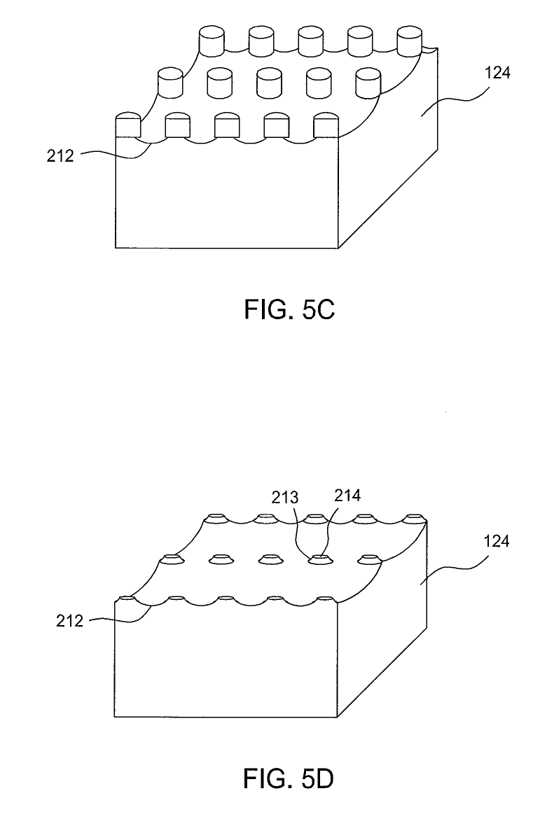

FIGS. 5A-D schematically illustrate a sequential process for making the top surface 134 of the conductive body 124 in the substrate support assembly 138 by chemical etching.

FIG. 5A illustrates that a layer of photoresist 210 is coated on the conductive body 124. A pattern 211 is then formed in the photoresist 210 by exposing the photoresist 210 to a UV light through a mask.

FIG. 5B illustrates the conductive body 124 with the photoresist 210 after the photoresist 210 has been developed.

The conductive body 124 with a patterned photoresist 210 is then dipped into a chemical etching solution to form a plurality of lowered areas 212 on exposed part of the conductive body 124, as shown in FIG. 5C.

FIG. 5D illustrates the conductive body 124 after the photoresist 210 has been removed. A plurality of islands 213 remain protruding from the plurality of lowered areas 212. In one embodiment, each island 213 may have a contact area 214 which is part of the original top surface of the conductive body 124 untouched by the etching solution. The contact area 214 is configured to be in contact with a substrate during process. Since the contact area 214 on each island 213 may preserve characteristics of the original top surface of the conductive body 124, such as flatness and roughness, the substrate may be evenly supported by each contact areas 214 in the same manner as it would by an unetched top surface of the conductive body 124.

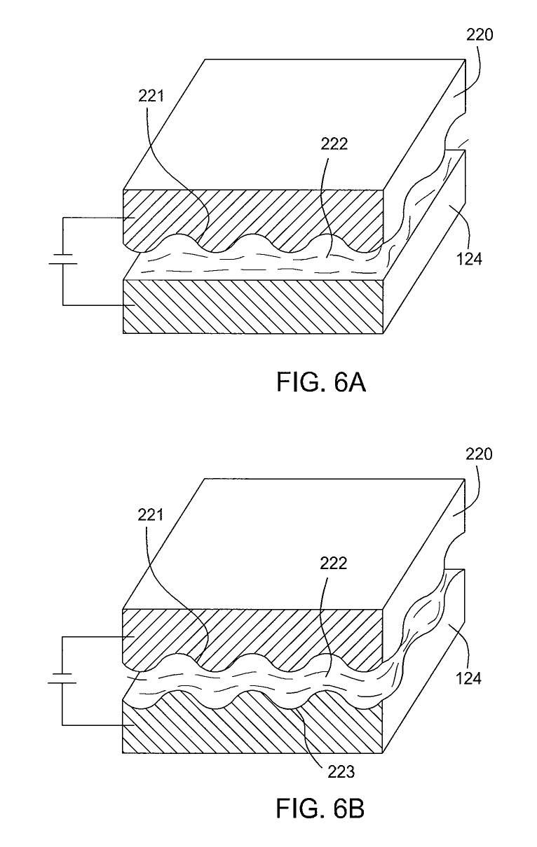

FIGS. 6A-B schematically illustrate an electropolishing method for manufacturing the top surface 134 of the conductive body 124 in the substrate support assembly 138 by electropolishing. A cathode 220 is positioned adjacent the conductive body 124 in a parallel manner in an electropolishing bath 222. The cathode 220 has a cathode pattern formed on a patterned surface 221. A power source 224 is applied between the conductive body 124 and the cathode 220 to provide electrical power to an electropolishing reaction. FIG. 6B illustrates that a complementary pattern 223 of the cathode pattern 221 has been formed on the conductive body 124 because electric field has a higher concentration at protruding surfaces than at concaving surfaces in an electrochemical reaction.

In one embodiment, an insulative coating, such as anodized layer, may be applied to the top surface 134 after the formation of the non-planar surface to improve emissivity. In one embodiment, the insulative coating has a surface finish between about 80 to about 200 micro-inches.

Although the present invention is described in a plasma reactor wherein the substrate is horizontally oriented, it could also apply to a reactor with vertical or inclined substrate orientation.

While the foregoing is directed to embodiments of the present invention, other and further embodiments of the invention may be devised without departing from the basic scope thereof, and the scope thereof is determined by the claims that follow.

1. A substrate support for using in a plasma reactor, comprising:
an electrically conductive body configured to be an electrode of the plasma reactor, wherein the electrically conductive body has a top surface configured for supporting a large area substrate and providing heat energy to the large area substrate, the top surface has a plurality of raised areas configured for contacting a back surface of the large area substrate, and the plurality of raised areas occupy less than about 50% of the surface area of the top surface.

2. The substrate support of claim 1, wherein the plurality of raised areas are smooth enough so that the back surface of the large area substrate is not subjective to damage from scratching.

3. The substrate support of claim 1, wherein the plurality of raised areas have a height of between about 0.001 inch to about 0.002 inch.

4. The substrate support of claim 1, wherein the plurality of raised areas are an array of raised islands evenly distributed across the top surface.

5. The substrate support of claim 4, wherein the distance between neighboring raised islands is between about 0.5 mm to about 3 mm.

6. The substrate support of claim 4, wherein the distance between neighboring raised islands is between about 1 mm to about 2 mm.

7. The substrate support of claim 4, wherein each of the plurality of raised islands has a circular contact area with a diameter of less than 0.5 mm.

8. The substrate support of claim 1, wherein the plurality of raised areas are formed from chemical etching.

9. The substrate support of claim 1, further comprising a heating element encapsulated in the electrically conductive body.

10. The substrate support of claim 1, further comprising an insulative coating covering the top surface of the electrically conductive body, wherein the insulative coating has a surface finish between about 80 micro-inches to about 200 micro-inches.

11. The substrate support of claim 1, wherein substrate support is configured to support the large area substrate having a plan surface area greater than about 0.25 meters squared.

12. A substrate support for processing a large area substrate, comprising:
an electrically conductive body configured for supporting the large area substrate and providing capacitive decoupling to the large area substrate, wherein the electrically conductive body has a plurality of raised areas evenly distributed on a top surface and continuously connected to a plurality of lowered areas on the top surface, the plurality of raised areas are configured to substantially contact a back surface of the large area substrate, and the plurality of raised areas occupy less than about 50% of the total surface area of the top surface; and
a heating element encapsulated in the electrically conductive body.

13. The substrate support of claim 12, further comprising one or more reinforcing elements.

14. The substrate support of claim 12, further comprising an insulative coating covers the top surface.

15. The substrate support of claim 12, wherein the plurality of raised areas and the plurality of lowered areas are formed from one of chemical etching, electropolishing, grinding, texturing and knurling.

16. The substrate support of claim 12, wherein the plurality of raised areas have a height relative to the plurality of lowered areas of between about 0.001 inch to about 0.002 inch.

17. The substrate support of claim 12, wherein each of the plurality of raised areas has a circular shape with a diameter of less than 0.5 mm.

18. A method for processing a large area substrate in a plasma chamber, comprising:
providing a substrate support having an electrically conductive body, wherein the electrically conductive body has a top surface configured for supporting a large area substrate and providing heat energy to the large area substrate, the top surface has a plurality of raised areas configured for contacting a back surface of the large area substrate, and the plurality of raised areas occupy less than about 50% of the surface area of the top surface;
positioning the large area substrate on the top surface of the substrate support;
introducing a precursor gas to the plasma chamber; and
generating a plasma of the precursor gas by applying an RF power between the electrically conductive body and an electrode parallel to the electrically conductive body.

19. The method of claim 18, further comprising heating the large area substrate using a heating element embedded in the electrically conductive body.

20. The method of claim 18, wherein providing the substrate support comprising etching the top surface of the electrically conductive body to generate the plurality of raised areas.
